(19) United States
(12) Patent Application Publication
(10) Pub. No.: US 2016/0064214 A1
(43) Pub. Date: Mar. 3, 2016

(54) TEMPLATE MANUFACTURING METHOD AND MANUFACTURING METHOD OF SEMICONDUCTOR DEVICE

(71) Applicant: Kabushiki Kaisha Toshiba, Minato-ku (JP)

(72) Inventor: Tadahito FUJISAWA, Yokkaichi (JP)

(73) Assignee: Kabushiki Kaisha Toshiba, Minato-ku (JP)

(21) Appl. No.: 14/600,176

(22) Filed: Jan. 20, 2015

(30) Foreign Application Priority Data
Aug. 28, 2014 (JP) 2014-173873

(51) Int. Cl. H01L 21/027; H01L 21/67; H01L 21/304; H01L 21/311; H01L 23/544

(52) U.S. Cl. CPC H01L 21/0273; H01L 21/31133; H01L 23/544; H01L 21/304; H01L 21/67259; H01L 2223/54426

(57) ABSTRACT

In a template manufacturing method of an embodiment, a first pattern is formed on a first template. A plurality of times of imprint processing using the first template is performed. A resist pattern is formed on a plurality of areas on a second template. At this time, processing of applying resist on the second template and processing of pressing the first pattern against the resist are repeatedly performed.

### CROSS-REFERENCE TO RELATED APPLICATIONS

This application is based upon and claims the benefit of priority from Japanese Patent Application No. 2014-173873, filed on Aug. 28, 2014; the entire contents of which are incorporated herein by reference.

### FIELD

An embodiment described herein relates generally to a template manufacturing method and a manufacturing method of a semiconductor device.

### BACKGROUND

Conventionally, high-resolution EB (Electronic beam) drawing is required to manufacture a template having a fine pattern. Further, to speed up imprint processing on a wafer, it is required to enlarge a shot area which is a one-time imprint processing area.

However, when giving priority to formation of a high-precision fine pattern, it is required to perform EB drawing on a large-scale area, so that the processing time of the EB drawing is very long. On the other hand, when giving priority to TAT (Turn Around Time) to shorten the processing time of the EB drawing, the accuracy of the EB drawing degrades.

As described above, it is difficult to achieve both high precision and high throughput when drawing one shot of template pattern by the EB drawing. As a method of realizing high precision and high throughput, there is a system that applies a photo repeater technique (a system that makes a template by imprint) (hereinafter referred to as a template making system). In the template making system, the positional accuracy of a pattern is determined by the positional accuracy of a stage, so that sub-nano order positional accuracy cannot be achieved. Even if a desired positional accuracy is achieved by introducing an interacting system in the template making system, an intra-device structure becomes complicated with respect to air flow and dust problems occur. Therefore, it is desired to realize high precision and high throughput manufacturing of template at low cost.

### BRIEF DESCRIPTION OF THE DRAWINGS

FIG. 1 is a diagram illustrating a configuration of a template manufacturing device according to a first embodiment;

FIGS. 2A to 2D are diagrams for explaining a processing procedure of an imprint process;

FIG. 3 is a diagram illustrating a configuration of a parent template;

FIG. 4 is a diagram illustrating a configuration of an element template;

FIG. 5 is a diagram for explaining a positioning between the element template and the parent template;

FIG. 6 is a flowchart illustrating a manufacturing processing procedure of the parent template; and

FIG. 7 is a diagram for explaining a manufacturing processing procedure of a child template.

### DETAILED DESCRIPTION

According to an embodiment, a template manufacturing method is provided. The template manufacturing method includes a first template forming process, a transfer process, and an etching process. In the first template forming process, a first pattern is formed on a first template. In the transfer process, a plurality of times of imprint processing using the first template is performed and a resist pattern corresponding to the first pattern is formed on a plurality of areas on a second template. In the etching process, etching from above the resist pattern is performed and a second pattern is formed on the second template. When the plurality of times of imprint processing are performed, coating processing, pressing processing, and resist pattern forming processing are repeatedly performed. The coating processing is processing to apply resist on the second template. The pressing processing is processing to press the first pattern against the applied resist. The resist pattern forming processing is processing to form the resist pattern in an area on which the resist is applied to.

Hereinafter, a template manufacturing method and a manufacturing method of semiconductor device according to an embodiment will be described in detail with reference to the attached drawings. The present invention is not limited by the embodiment.

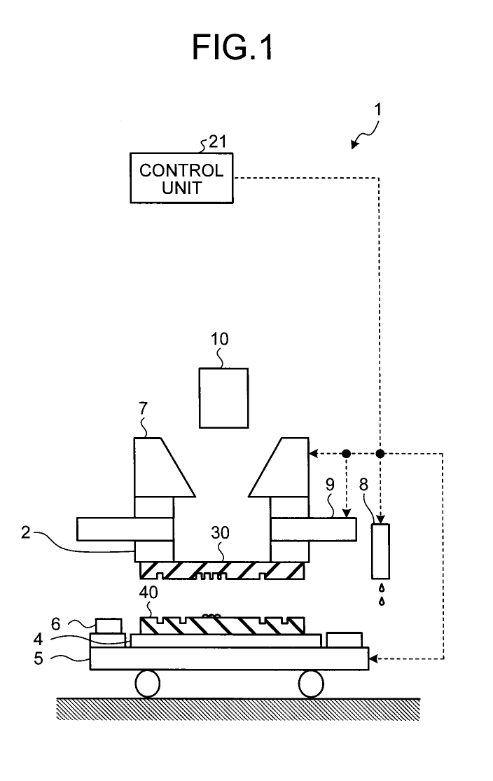

FIG. 1 is a diagram illustrating a configuration of a template manufacturing device according to a first embodiment. The template manufacturing device 1 is a device that transfers a template pattern of an element template 30 to a parent template (a master template) 40. In the template manufacturing device 1, a technique of photo repeater is applied to a template making technique.

The template manufacturing device 1 transfers a template pattern to be transferred (hereinafter referred to as an element pattern Y1), which is formed in a functional area of the element template 30, to the parent template 40. The template manufacturing device 1 of the present embodiment forms the parent template 40 by transferring the element pattern Y1 onto the parent template 40 a plurality of times. In the description below, a template pattern which is formed on the parent template 40 and which is to be transferred to a child template or the like is referred to as a parent pattern Z.

The parent template 40 is an original template which is used when transferring the parent pattern Z to a child template or the like. When the parent pattern Z is formed on the parent template 40, the parent template 40 becomes a substrate to which a pattern is transferred, and when the parent pattern Z is transferred to another substrate such as a child template, the parent template 40 becomes a mold substrate.

The element template 30 is a mold substrate, and an element pattern Y1 such as a circuit pattern is formed on the element template 30. The element pattern Y1 formed on the element template 30 is a part of patterns which are obtained by dividing the parent pattern Z to be formed on the parent template 40 for each function or for each repeating block. In other words, the element pattern Y1 is any one of first divided patterns obtained by dividing the parent pattern Z for each function or a second divided pattern obtained by dividing the parent pattern Z for each repeating block.

In the parent template 40, the same pattern (such as a functional pattern) is repeatedly arranged. For example, a plurality of the same chips may be arranged on the parent template 40. In this case, one chip pattern is formed on the element template 30 as the element pattern Y1.

In the present embodiment, the template manufacturing device 1 manufactures the parent template 40 by repeating imprint processing using the element template 30 a plurality of times on the parent template 40. Specifically, the element pattern Y1 formed on the element template 30 is transferred to a plurality of positions on the parent template 40.

The template manufacturing device 1 of the present embodiment performs alignment of the element templates 30 to the parent template 40 by using a plurality of alignment marks formed on the element template 30 and a plurality of alignment marks formed on the parent template 40.

In the description below, the alignment mark formed on the element template 30 is referred to as an element alignment mark. The alignment mark formed on the parent template 40 is referred to as a parent alignment mark.

The imprint processing using the element template 30 is performed on the parent template 40 a plurality of times. Therefore, the parent alignment marks used for each imprint processing are arranged onto the parent template 40 at positions according to each imprint processing.

For example, on the parent template 40, from first parent alignment marks used for the first imprint processing to Nth parent alignment marks (N is a natural number) used for the Nth imprint processing are arranged.

In the same manner, on the element template 30, from first element alignment marks used for the first imprint processing to Nth element alignment marks used for the Nth imprint processing are arranged.

A plurality of parent alignment marks and a plurality of element alignment marks are used for each imprint processing. For example, four parent alignment marks and four element alignment marks are used for each imprint processing.

The parent alignment marks and the element alignment marks are formed by the EB drawing (Electronic beam lithography). Thereby, the alignment processing is performed by using high-precision parent alignment marks and element alignment marks.

The template manufacturing device 1 includes an original template stage 2, a substrate chuck 4, a sample stage 5, a reference mark 6, an alignment sensor 7, a liquid dropping device 8, a stage base 9, and a UV light source 10. The template manufacturing device 1 of the present embodiment further includes a control unit 21.

The parent template 40 is mounted on the sample stage 5, and the sample stage 5 moves in a plane (a horizontal plane) in parallel with the mounted parent template 40. When dropping resist onto the parent template 40 as a transfer material, the sample stage 5 moves the parent template 40 to a position below the liquid dropping device 8. When pressing the element template 30 against the parent template 40, the sample stage 5 moves the parent template 40 to a position below the element template 30.

The substrate chuck 4 is provided on the sample stage 5. The sample stage 5 fixes the parent template 40 to a predetermined position on the sample stage 5 by using the substrate chuck 4. Further, the reference mark 6 is provided on the sample stage 5. The reference mark 6 is a mark for detecting the position of the sample stage 5. The reference mark 6 is used for positioning when the parent template 40 is loaded onto the sample stage 5.

The original template stage 2 is provided to the bottom side (the side facing the parent template 40) of the stage base 9. The stage base 9 fixes the element template 30 to a predetermined position by vacuum suction or the like from the rear surface (the surface on which the element pattern Y1 is not formed) of the element template 30 by using the original template stage 2.

The alignment sensor 7 is provided on the stage base 9. The alignment sensor 7 is a sensor that detects the position of the parent template 40 and the position of the element template 30. The alignment sensor 7 of the present embodiment detects the position of the parent template 40 based on the positions of the parent alignment marks. The alignment sensor 7 detects the position of the element template based on the positions of the element alignment marks. The alignment sensor 7 detects a superposition shift amount between the parent alignment marks and the element alignment marks.

The stage base 9 holds the element template 30 by the original template stage 2. The stage base 9 presses the element pattern Y1 of the element template 30 against the resist on the parent template 40. The stage base 9 moves in the up-down direction (vertical direction), so that the stage base 9 presses the element template 30 against the resist and pulls (separates) the element template 30 away from the resist. The resist used for the imprint is, for example, a photo-curable resin (photo-curable material) or the like.

The stage base 9 performs alignment between the parent template 40 and the element template 30 by a die-by-die method. The stage base 9 performs the alignment between the parent template 40 and the element template 30 based on the detection result of the superposition shift amount detected by the alignment sensor 7. The stage base 9 performs alignment processing so that the superposition shift amount between the parent alignment marks and the element alignment marks is within a predetermined range.

In the present embodiment, the element pattern Y1 is transferred to one parent template 40 a plurality of times. Therefore, every time the imprint processing is performed, the detection processing of the superposition shift amount between the parent alignment marks and the element alignment marks and the alignment processing are performed.

The liquid dropping device 8 is a device that drops resist on the parent template 40 by an ink jet method. An ink jet head (not illustrated in FIG. 1) included in the liquid dropping device 8 has a plurality of micropores for ejecting droplets of resist. The liquid dropping device 8 arranges resist in a position where the element pattern Y1 is pressed in an area on the parent template 40.

The UV light source 10 is a light source that emits UV light and is provided above the stage base 9. The UV light source 10 emits the UV light from above the element template 30 while the element template 30 is pressed against the resist.

The control unit 21 is connected to each component of the template manufacturing device 1 and controls each component. FIG. 1 illustrates a state in which the control unit 21 is connected to the sample stage 5, the alignment sensor 7, the liquid dropping device 8, and the stage base 9, and omits connections to other components. When the control unit 21 transfers the element pattern Y1 to the parent template 40, the control unit 21 controls the sample stage 5, the alignment sensor 7, the liquid dropping device 8, the stage base 9, and the like.

When the imprint onto the parent template 40 is performed, the parent template 40 mounted on the sample stage 5 is moved to a position immediately below the liquid dropping device 8. Then, the resist is dropped onto an area to which the element pattern Y1 is transferred on the parent template 40. At this time, the resist is dropped onto an area to which one element pattern Y1 is transferred.

Thereafter, the parent template 40 on the sample stage 5 is moved to a position immediately below the element template 30. Then, the element template 30 is pressed against the resist on the parent template 40. At this time, the element template 30 and the resist are contacted with each other for a contact time according to the element pattern Y1.

After the element template 30 and the resist are contacted with each other for a predetermined time, the UV light source 10 emits UV light to the resist in this state, so that the resist is hardened. Thereby, a transfer pattern corresponding to the element pattern Y1 is patterned onto the resist on the parent template 40.

Thereafter, the imprint processing of the element pattern Y1 is performed on the next position on the parent template 40. When the imprint processing of the element pattern Y1 has been performed on all setting positions on the parent template 40, the imprint processing onto the parent template 40 is completed.

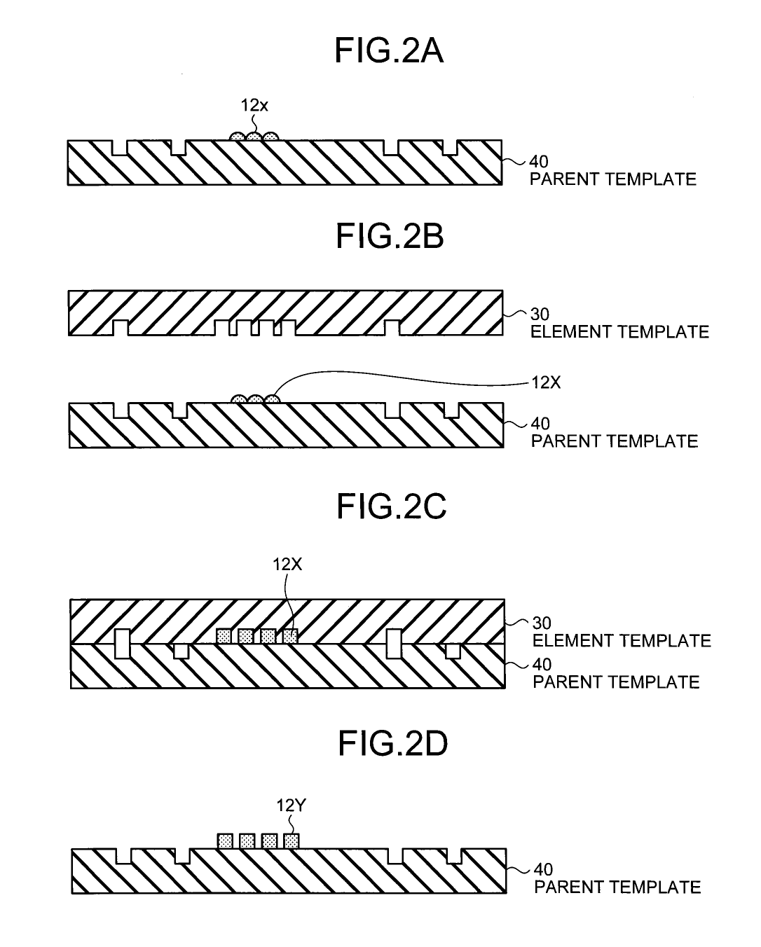

Here, a processing procedure of an imprint process will be described. FIGS. 2A to 2D are diagrams for explaining the processing procedure of the imprint process. FIGS. 2A to 2D illustrate cross-sectional diagrams of the parent template 40 and the element template 30 during the imprint process.

As illustrated in FIG. 2A, resist 12X is dropped onto the upper surface of the parent template 40. Thereby, each droplet of the resist 12X dropped onto the parent template 40 spreads in an area to which the element pattern Y1 is transferred on the surface of the parent template 40.

Then, as illustrated in FIG. 2B, the element template 30 is moved toward the resist 12X from above the upper surface of the parent template 40. Then, as illustrated in FIG. 2C, the element template 30 is pressed against the resist 12X. In this way, when the element template 30, which is made by engraving a quartz substrate or the like, is contacted with the resist 12X, the resist 12X flows into the element pattern Y1 by a capillary phenomenon.

After the resist 12X is caused to fill the element template 30 for a predetermined time, UV light is irradiated. Thereby, the resist 12X is hardened. Then, as illustrated in FIG. 2D, the element template 30 is separated from the hardened resist 12Y. Thereby, a resist pattern, which is the reverse of the element pattern Y1, is formed on the parent template 40.

Thereafter, the parent template 40 is etched from above the resist pattern, so that a pattern corresponding to the resist pattern is formed on the parent template 40.

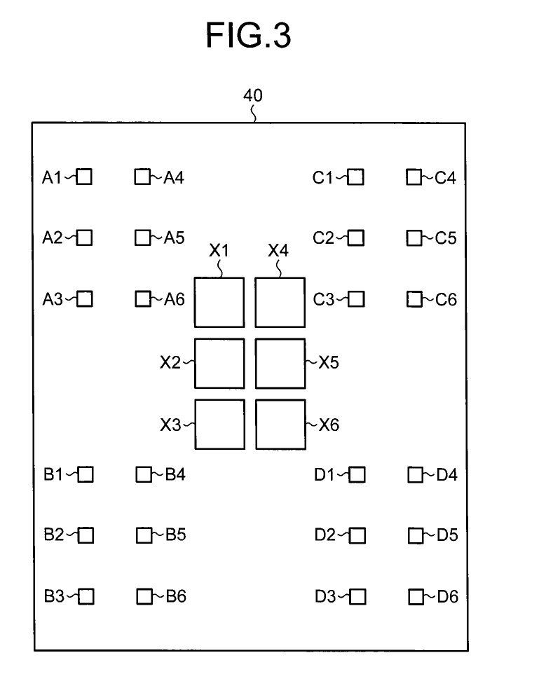

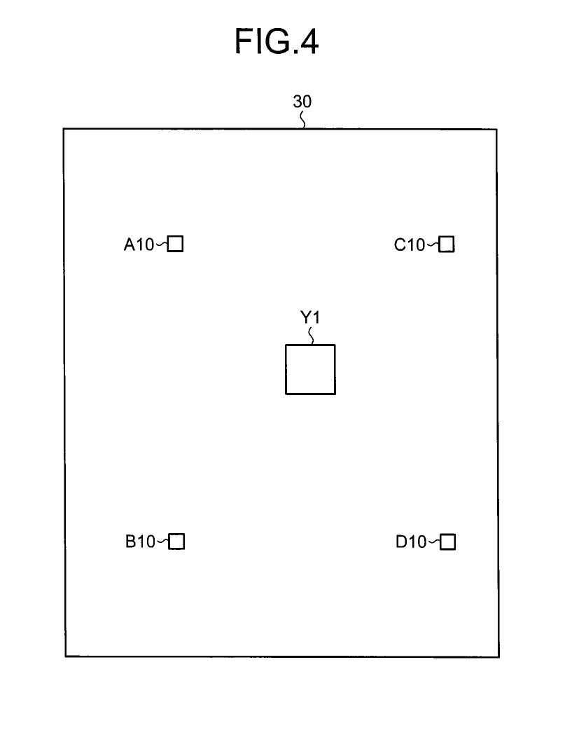

Next, configurations of the parent template 40 and the element template 30 will be described. FIG. 3 is a diagram illustrating the configuration of the parent template. FIG. 4 is a diagram illustrating the configuration of the element template. FIG. 3 illustrates a top view of the parent template 40. FIG. 4 illustrates a top view of the element template 30. FIG. 3 omits a peripheral pattern described later.

On the parent template 40, a plurality of element pattern areas X1 to X6, which are areas to which the element pattern Y1 is transferred, are arranged. One element pattern Y1 is transferred to each of the element pattern areas X1 to X6. In the description below, the element pattern areas X1 to X6 may be collectively referred to as the element pattern areas.

Further, on the parent template 40, for example, parent alignment marks are arranged around the element pattern areas. Specifically, on the parent template 40, parent alignment marks A1 to A6, B1 to B6, C1 to C6, and D1 to D6 are arranged.

The parent alignment marks A1, B1, C1, and D1 are used when the element pattern Y1 is transferred to the element pattern area X1. The parent alignment marks A2, B2, C2, and D2 are used when the element pattern Y1 is transferred to the element pattern area X2. The parent alignment marks A3, B3, C3, and D3 are used when the element pattern Y1 is transferred to the element pattern area X3.

The parent alignment marks A4, B4, C4, and D4 are used when the element pattern Y1 is transferred to the element pattern area X4. The parent alignment marks A5, B5, C5, and D5 are used when the element pattern Y1 is transferred to the element pattern area X5. The parent alignment marks A6, B6, C6, and D6 are used when the element pattern Y1 is transferred to the element pattern area X6. In the description below, the parent alignment marks A1 to A6, B1 to B6, C1 to C6, and D1 to D6 may be referred to as the parent alignment marks.

On the element template 30, the element pattern Y1 is arranged. Further, on the element template 30, for example, element alignment marks A10, B10, C10, and D10 are arranged around the element pattern Y1. The element alignment marks A10, B10, C10, and D10 are used when the element pattern Y1 is transferred to the element pattern areas X1 to X6.

The template manufacturing device 1 performs the alignment processing between the parent template 40 and the element template 30 by a die-by-die method. For example, the imprint processing onto the parent template 40 is performed so that the element pattern Y1 is superposed on the element pattern area X1. At this time, the alignment processing is performed so that the parent alignment marks corresponding to the element pattern area X1 and the element alignment marks corresponding to the element pattern Y1 are superposed on each other.

Specifically, the alignment processing is performed so that the parent alignment marks A1, B1, C1, and D1 are superposed on the element alignment marks A10, B10, C10, and D10, respectively.

After the alignment processing is performed so that the parent alignment marks A1, B1, C1, and D1 are superposed on the element alignment marks A10, B10, C10, and D10, respectively, the imprint processing onto the parent template 40 is performed. In the description below, the element alignment marks A10, B10, C10, and D10 may be referred to as the element alignment marks.

The number of the element alignment marks formed on the element template 30 is not limited to four, but may be any number. In the same manner, the number of the parent alignment marks formed on the parent template 40 is not limited to four, but may be any number. The shape of the element alignment marks and the parent alignment marks is not limited to a rectangular shape, but may be any shape.

The arrangement of the element pattern Y1 and the element alignment marks illustrated in FIG. 4 is an example. Therefore, the element pattern Y1 and the element alignment marks may be arranged at any positions.

The arrangement of the element pattern areas X1 to X6 and the parent alignment marks illustrated in FIG. 3 is an example. Therefore, the element pattern areas X1 to X6 and the parent alignment marks may be arranged at any positions.

In FIG. 3, a case is described in which the element pattern areas arranged on the parent template 40 are six element pattern areas X1 to X6. However, the number of the element pattern areas arranged on the parent template 40 is not limited.

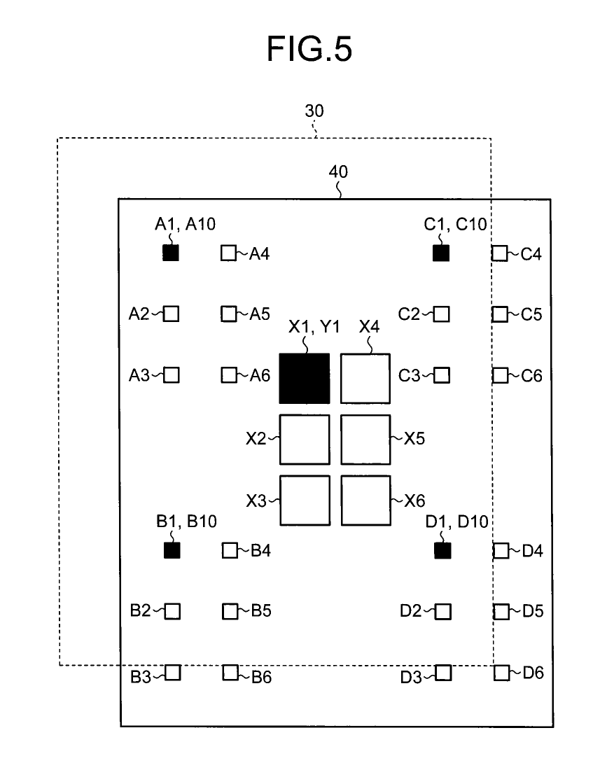

FIG. 5 is a diagram for explaining a positioning between the element template and the parent template. FIG. 5 illustrates a top view of a state in which the element template 30 and the parent template 40 are superposed on each other. FIG. 5 omits the peripheral pattern described later.

As described above, when the alignment processing is performed, the parent alignment mark A1 and the element alignment mark A10 are superposed on each other and the parent alignment mark B1 and the element alignment mark B10 are superposed on each other. In the same manner, the parent alignment mark C1 and the element alignment mark C10 are superposed on each other and the parent alignment mark D1 and the element alignment mark D10 are superposed on each other. Thereby, the element pattern Y1 is superposed on the element pattern area X1, so that in this state, the element template 30 is pressed against the resist on the parent template 40.

After the imprint processing onto the element pattern area X1 is completed, the imprint processing onto the element pattern area X2 is performed. Specifically, the imprint processing onto the parent template 40 is performed so that the element pattern Y1 is superposed on the element pattern area X2. At this time, the alignment processing is performed so that the parent alignment marks corresponding to the element pattern area X2 and the element alignment marks corresponding to the element pattern Y1 are superposed on each other. Specifically, the alignment processing is performed so that the alignment marks A2 and A10 are superposed on each other, the alignment marks B2 and B10 are superposed on each other, the alignment marks C2 and C10 are superposed on each other, and the alignment marks D2 and D10 are superposed on each other.

Further, the imprint processing onto the parent template 40 is performed so that the element pattern Y1 is superposed on the element pattern area X3. Further, the imprint processing onto the parent template 40 is performed so that the element pattern Y1 is superposed on the element pattern area X4. Further, the imprint processing onto the parent template 40 is performed so that the element pattern Y1 is superposed on the element pattern area X5. Further, the imprint processing onto the parent template 40 is performed so that the element pattern Y1 is superposed on the element pattern area X6.

The element pattern Y1 may be transferred to the element pattern areas X1 to X6 in any order. A case will be described below, in which the element pattern Y1 is transferred to the element pattern areas X1, X2, X3, X4, X5, and X6 in this order.

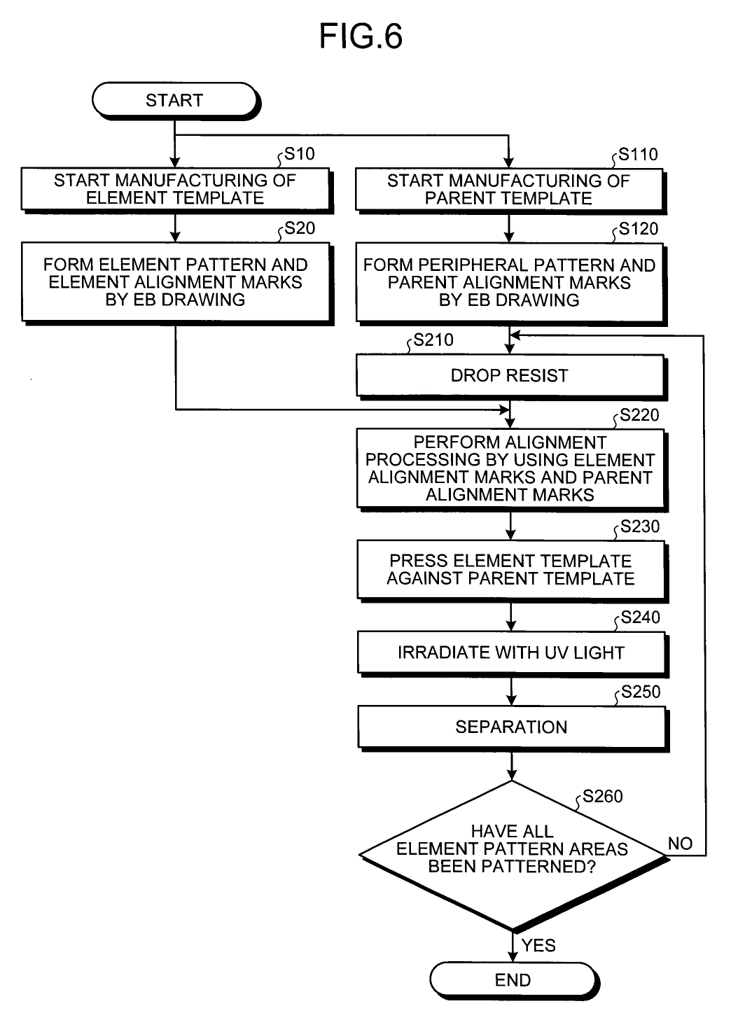

Next, a manufacturing processing procedure of the parent template will be described. FIG. 6 is a flowchart illustrating a manufacturing processing procedure of the parent template. Before the imprint processing onto the parent template 40 is performed, the element template 30 is manufactured in advance.

Specifically, when the manufacturing of the element template 30 is started (step S10), the element pattern Y1 and the element alignment marks are formed on the element template 30. The element pattern Y1 and the element alignment marks are formed by an EB drawing device (step S20).

When the manufacturing of the parent template 40 is started (step S110), the peripheral pattern and the parent alignment marks are formed on the parent template 40. The peripheral pattern and the parent alignment marks are formed by the EB drawing device (step S120).

The peripheral pattern is a pattern that is formed in an area, in which neither the element pattern Y1 nor the parent alignment marks are formed, in the parent pattern Z. In other words, the parent template 40 includes an area to which the element pattern Y1 is transferred, areas in which the parent alignment marks are formed, and an area in which the peripheral pattern is formed. The peripheral pattern is, for example, a peripheral circuit pattern.

As described above, in the present embodiment, the element alignment marks are formed on the element template 30 by using the EB drawing device. Further, the parent alignment marks are formed on the parent template 40 by using the EB drawing device.

Thereafter, in the template manufacturing device 1, the parent template 40 on which the parent alignment marks are formed is fixed on the sample stage 5. Further, in the template manufacturing device 1, the element template 30 on which the element alignment marks are formed is fixed to the original template stage 2.

Then, the liquid dropping device 8 drops the resist 12X to the element pattern area X1 on the parent template 40 (step S210). The stage base 9 moves the parent template 40 to a position where the element pattern Y1 is superposed on the element pattern area X1.

The alignment sensor 7 detects a superposition shift amount between the parent alignment marks A1, B1, C1, and D1 and the element alignment marks A10, B10, C10, and D10. The stage base 9 performs the alignment between the parent template 40 and the element template 30 based on the detection result of the superposition shift amount detected by the alignment sensor 7. In this way, the alignment processing is performed by using the parent alignment marks A1, B1, C1, and D1 and the element alignment marks A10, B10, C10, and D10 (step S220).

The template manufacturing device 1 presses the element template 30 on which the alignment processing is performed against the parent template 40 (step S230). After the element template 30 and the resist 12X are contacted with each other for a predetermined time, the resist 12X is irradiated with UV light (step S240). Thereby, the resist 12X is hardened.

Thereafter, the element template 30 is separated from the hardened resist 12Y (step S250). Thereby, a resist pattern, which is the reverse of the element pattern Y1, is formed on the parent template 40.

Thereafter, the control unit 21 checks whether or not all of the element pattern areas X1 to X6 have been patterned by the element pattern Y1 (step S260). When not all of the element pattern areas X1 to X6 have been patterned (step S260, No), the template manufacturing device 1 performs the processing of steps S210 to S260 on an element pattern area that has not been patterned.

For example, the template manufacturing device 1 performs the processing of steps S210 to S260 on the element pattern area X2. In the same manner, the template manufacturing device 1 performs the processing of steps S210 to S260 on each of the element pattern areas X3 to X6. Thereby, the element pattern Y1 is transferred to the element pattern areas X1 to X6.

When all the element pattern areas X1 to X6 have been patterned (step S260, Yes), the manufacturing processing of the parent template 40 is completed. The peripheral pattern of the parent template 40 may be formed at any timing. For example, the peripheral pattern may be formed earlier than the parent alignment marks. The peripheral pattern may be formed after the element pattern Y1 is formed on the element pattern areas X1 to X6.

Next, processing for manufacturing a child template by using the parent template 40 will be described. The child template is manufactured by transferring the parent pattern Z of the parent template 40 to the child template.

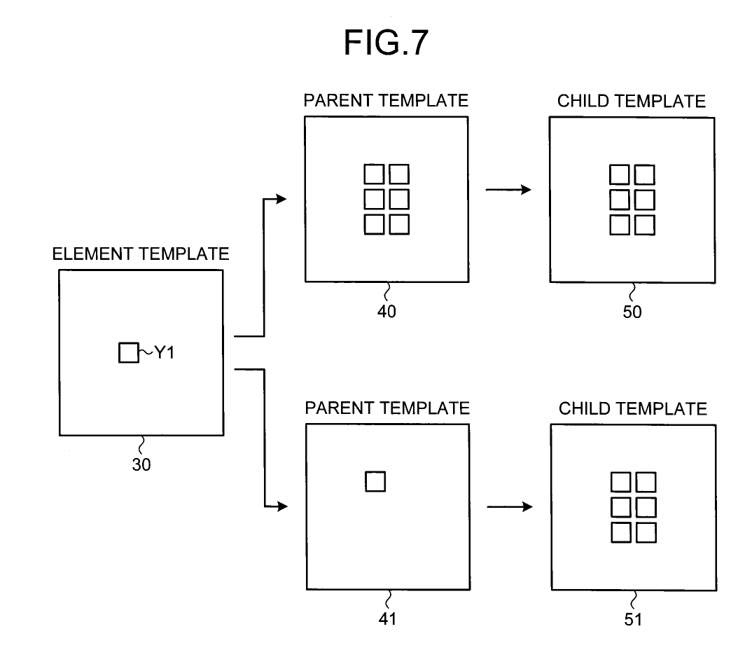

FIG. 7 is a diagram for explaining a manufacturing processing procedure of the child template. After the element template 30 is manufactured, the element pattern Y1 is transferred to either of parent templates 40 and 41. The parent template 40 is a template to which a plurality of the element patterns Y1 are transferred. The parent template 41 is a template to which one element pattern Y1 is transferred. In this way, the element pattern Y1 may be transferred to a plurality of positions on a template or may be transferred to one position on a template. When the parent template 40 is manufactured, the transfer processing of the element pattern Y1 is repeated a plurality of times.

When manufacturing a child template 50 by using the parent template 40 to which a plurality of element patterns Y1 are transferred, the parent pattern Z including a plurality of element patterns Y1 is transferred to the child template 50 by one-time imprint processing.

When manufacturing a child template 51 by using the parent template 41 to which one element pattern Y1 is transferred, the transfer processing of the element pattern Y1 is repeated a plurality of times. For example, the template manufacturing device 1 manufactures the child template 51 by using the parent template 41.

The transfer processing of the element pattern Y1 may be repeated a plurality of times in both cases where a parent template 42 (not illustrated in FIG. 7) is manufactured and where a child template 52 (not illustrated in FIG. 7) is manufactured. In this case, for example, the transfer processing using the element template 30 is repeated two times, so that the parent template 42 is manufactured. Then, the transfer processing using the parent template 42 is repeated three times, so that the child template 52 is manufactured.

When a semiconductor device (semiconductor integrated circuit) is manufactured, the parent template 40 or the child template 50, 51, or 52 is used. Hereinafter, a case will be described in which the semiconductor device is manufactured by using the child template 50.

For example, the element template 30, the parent template 40, and the child template 50 are manufactured for each layer of a wafer process. Then, the semiconductor device is manufactured by using the child template 50. Specifically, the parent template 40 is manufactured by using the element template 30, and the child template 50 is manufactured by using the parent template 40. Then, the imprint processing is performed on a wafer (semiconductor substrate) coated with resist by using the child template 50, and thereby, a resist pattern is formed on the wafer. Then, a lower layer of the wafer is etched by using the resist pattern as a mask. Thereby, an actual pattern corresponding to the resist pattern is formed on the wafer. When manufacturing a semiconductor device, the manufacturing of the element template 30, the manufacturing of the parent template 40, the manufacturing of the child template 50, the imprint processing onto a wafer by using the child template 50, the etching processing, and the like described above are repeated for each layer.

As described above, according to the embodiment, the element pattern Y1 and the element alignment marks are formed on the element template 30 by using the EB drawing device. Further, the parent alignment marks are formed on the parent template 40 by using the EB drawing device. Then, the element pattern Y1 is transferred to the parent template 40 a plurality of times by the imprint processing using the element template 30.

When the element pattern Y1 is transferred to the parent template 40 a plurality of times, at least the following three processing operations are repeated:

(1) Processing in which the resist 12X is coated on the parent template 40

(2) Processing in which the element template 30 is aligned with the parent template 40 by using the element alignment marks and some of the parent alignment marks

(3) Processing in which a resist pattern corresponding to the element pattern Y1 is formed on the parent template 40 by using the element template 30

After the element pattern Y1 is transferred a plurality of times, etching is performed from above the parent template 40. Thereby, a pattern corresponding to the element pattern Y1 is formed on the parent template 40.

In this way, the template manufacturing device 1 performs the alignment processing without using an interacting system, so that it is possible to manufacture the parent template 40 at low cost.

The alignment processing is performed by using the parent alignment marks and the element alignment marks, which are formed by the EB drawing, so that when the alignment processing is performed, a positional accuracy error of the sample stage 5 is not added. Therefore, it is possible to perform high-precision alignment processing. Thus, the parent template 40 can be manufactured with positional accuracy (for example, positional accuracy of sub-nano order) of the parent alignment marks and the element alignment marks, which are formed by the EB drawing. As a result, it is possible to realize high-precision CDU (Critical Dimension Uniformity) accuracy in a large area, so that it is possible to improve yield rate and device performance of semiconductor devices.

The amount of the EB drawing used for the element template 30 and the parent template 40 is small, so that the parent template 40 can be manufactured in a short time. The imprint processing is performed on the parent template 40 by using the element template 30, so that the parent template 40 can be manufactured in a short time.

Therefore, according to the present embodiment, it is possible to realize high precision and high throughput manufacturing of template at low cost.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template manufacturing method comprising:
forming a first pattern on a first template;
performing a plurality of times of imprint processing using the first template, and forming a resist pattern corresponding to the first pattern on a plurality of areas on a second template; and
performing etching from above the resist pattern, and forming a second pattern on the second template,
wherein when performing the plurality of times of imprint processing,
processing of applying resist on the second template,
processing of pressing the first pattern against the applied resist, and
processing of forming the resist pattern in an area on which the resist is applied to,
are repeatedly performed.

2. The template manufacturing method according to claim 1, wherein
before performing the plurality of times of imprint processing, the first pattern and a first alignment mark are formed on the first template and a second alignment mark is formed on the second template, and
when forming the resist pattern, processing of aligning the first template with the second template is performed by using the first and the second alignment marks.

3. The template manufacturing method according to claim 2, wherein
a plurality of pattern formation areas to which the first pattern is transferred are set on the second template, and
the second alignment mark is formed in a position corresponding to the pattern formation area for each pattern formation area.

4. The template manufacturing method according to claim 3, wherein the processing of aligning the first template with the second template is performed by a die-by-die method for each pattern formation area.

5. The template manufacturing method according to claim 1, wherein the first pattern is any one of first divided patterns obtained by dividing the second pattern for each function.

6. The template manufacturing method according to claim 1, wherein the first pattern is a second divided pattern obtained by dividing the second pattern for each repeating block.

7. The template manufacturing method according to claim 1, wherein a peripheral pattern of the second pattern is formed on the second template.

8. The template manufacturing method according to claim 1, wherein the second template is a template used when a third template is formed in imprint processing.

9. The template manufacturing method according to claim 1, wherein the second template is a template used when a circuit pattern is formed on a semiconductor substrate in imprint processing.

10. A manufacturing method of a semiconductor device, comprising:
forming a first pattern on a first template;
performing a plurality of times of imprint processing using the first template, and forming a resist pattern corresponding to the first pattern on a plurality of areas on a second template;
performing etching from above the resist pattern, and forming a second pattern on the second template; and
forming a circuit pattern corresponding to the second pattern on a semiconductor substrate by using the second template,
wherein when performing the plurality of times of imprint processing,
processing of applying resist on the second template, processing of pressing the first pattern against the applied resist, and
processing of forming the resist pattern in an area on which the resist is applied to,
are repeatedly performed.

11. The manufacturing method of a semiconductor device according to claim 10, wherein
before performing the plurality of times of imprint processing, the first pattern and a first alignment mark are formed on the first template and a second alignment mark is formed on the second template, and
when forming the resist pattern, processing of aligning the first template with the second template is performed by using the first and the second alignment marks.

12. The manufacturing method of a semiconductor device according to claim 11, wherein
a plurality of pattern formation areas to which the first pattern is transferred are set on the second template, and
the second alignment mark is formed in a position corresponding to the pattern formation area for each pattern formation area.

13. The manufacturing method of a semiconductor device according to claim 12, wherein the processing of aligning the first template with the second template is performed by a die-by-die method for each pattern formation area.

14. The manufacturing method of a semiconductor device according to claim 10, wherein the first pattern is any one of first divided patterns obtained by dividing the second pattern for each function.

15. The manufacturing method of a semiconductor device according to claim 10, wherein the first pattern is a second divided pattern obtained by dividing the second pattern for each repeating block.

16. The manufacturing method of a semiconductor device according to claim 10, wherein a peripheral pattern of the second pattern is formed on the second template.

17. The manufacturing method of a semiconductor device according to claim 10, wherein
the second template is a template used when a third template is formed in imprint processing, and
the third template is formed by using the second template and the circuit pattern is formed on the semiconductor substrate by using the third template.

18. The manufacturing method of a semiconductor device according to claim 10, wherein
the second template is a template used when the circuit pattern is formed on the semiconductor substrate in imprint processing, and
the circuit pattern is formed on the semiconductor substrate by pressing the second template against resist on the semiconductor substrate.

19. A template manufacturing device comprising:
a stage base configured to fix a first template on which a first pattern is formed;
a sample stage configured to fix a second template; and
a control unit configured to control the stage base and the sample stage so that a resist pattern corresponding to the first pattern is formed on a plurality of areas on the second template by a plurality of times of imprint processing using the first template,
wherein when performing the plurality of times of imprint processing, the control unit controls the stage base and the sample stage so that
processing of applying resist on the second template, and
processing of forming the resist pattern in an area on which the resist is applied by pressing the first pattern against the applied resist,
are repeatedly performed.

20. The template manufacturing device according to claim 19, further comprising:
an alignment sensor configured to detect positions of a first alignment mark formed on the first template and a second alignment mark formed on the second template,
wherein the control unit performs processing to align the first template with the second template based on a detection result of the positions.
